(19) United States
(12) Patent Application Publication
(10) Pub. No.: US 2024/0190281 A1
(43) Pub. Date: Jun. 13, 2024

(54) ELECTRIC VEHICLE SUPPLY EQUIPMENT (EVSE) POWERED APPLIANCE WITH LOAD SHEDDING

(71) Applicant: Midea Group Co., Ltd., Beijiao (CN)

(72) Inventors: John Kenneth Hooker, Louisville, KY (US); Hieu Manh Vu, Louisville, KY (US); Isabelle Catlett, Frankfort, KY (US)

(21) Appl. No.: 18/078,920

(22) Filed: Dec. 9, 2022

(51) Int. Cl. B60L 53/62; G01R 31/327; H01H 9/56; H01H 47/00

(52) U.S. Cl. CPC B60L 53/62; G01R 31/3274; H01H 9/563; H01H 47/002

(57) ABSTRACT

An Electric Vehicle Supply Equipment (EVSE) powered apparatus includes an input power receptacle capable of receiving the plug of an EVSE device to power the apparatus using power supplied by the EVSE device, and a user-actuatable control that may be used to transition the EVSE device from a connected but not charging state to a charging state after the plug has been inserted into the input power receptacle to cause the EVSE device to transition to the charging state and supply power through the plug. In some instances, one or more output power receptacles may be provided to enable various external electrically-powered devices to be plugged into the apparatus and powered by the EVSE device, while in other instances, the apparatus itself may be an appliance, tool, or other high power device, such that the apparatus is powered directly from the EVSE device.

### BACKGROUND

As the world transitions away from fossil fuel powered vehicles to electric vehicles, the need has arisen for providing owners of electric vehicles (EVs) with convenient and fast charging of their vehicles wherever they may be. However, despite the fact that the number of publicly-accessible charging stations, also referred to as Electric Vehicle Supply Equipment (EVSE) devices, continues to grow, it is expected that many vehicle owners will primarily charge their vehicles at home, e.g., in a garage or carport where they park their vehicles while at home.

Moreover, while it is possible to charge electric vehicles from the standard wall outlets found in many homes, which in the United States operate at 120 VAC, charging from such wall outlets (generally using what are generally referred to as Level 1 chargers) can be exceptionally slow, and as a result, many vehicle owners prefer to install higher output, Level 2 EVSE devices in their homes in order to accelerate the charging process. Level 2 EVSE devices generally must be supplied with 208-240 VAC power, and as many garages and carports where vehicles are stored were not originally provided with 208-240 VAC service, many vehicle owners are required to have an electrician come and install an appropriate 208-240 VAC electrical circuit whenever a Level 2 EVSE device is installed at their home.

Many Level 2 EVSE devices are hard-wired, rather than being plugged into a socket or receptacle, so despite the fact that an EVSE device may not be actively charging a vehicle a good portion of the time, the 208-240 VAC electric circuit to which it is coupled is generally not available for any other use. There are, however, a wide variety of tools, appliances and other high power devices that use such an electrical circuit, and many are well suited for use in a garage or otherwise outside the main structure of a home, including, for example, heaters such as garage heaters, air conditioners, vacuums such as whole house or shop vac systems, tools such as table saws and other woodworking equipment, arc welders, etc. When a Level 2 EVSE device is hard-wired to its electrical circuit, however, these other high power devices are only usable if a different electrical circuit, typically with a suitable socket or receptacle, is provided in the area. Installing additional electrical circuits, however, can be expensive, and in some instances, may exceed the capacity of the existing electrical panels in the home, requiring even more expensive upgrades to the home's existing infrastructure.

### SUMMARY

The invention addresses these and other problems associated with the art by providing an appliance and method of using the same that includes an input power receptacle that is capable of receiving the plug of an Electric Vehicle Supply Equipment (EVSE) device to power the appliance using power supplied by the EVSE device. Moreover, the appliance includes load shedding functionality that is responsive to a utility control signal provided through the EVSE plug to controllably vary the power consumption of one or more loads in the appliance.

Therefore, consistent with one aspect of the invention, an appliance may be configured to receive power from an Electric Vehicle Supply Equipment (EVSE) device, and may include at least one housing, an input power receptacle disposed on the at least one housing and configured to receive the plug of the EVSE device to establish a physical connection therebetween, the input power receptacle including one or more line power inputs configured to receive power from the plug of the EVSE device, at least one electrical load disposed in the at least one housing, and a control circuit coupled to the input power receptacle and the at least one electrical load to supply power received over the one or more line power inputs to the at least one electrical load. The control circuit may further be configured to, in response to a demand response signal received from the EVSE device through the input power receptacle, selectively reduce the power supplied to the at least one electrical load while the at least one electrical load is active to reduce power consumption by the at least one electrical load to meet an allowed power indicated by the demand response signal.

In some embodiments, the control circuit is configured to supply power to the at least one electrical load using an alternating current (AC) power signal received over the one or more line power inputs, and the control circuit includes a TRIAC device configured to control the power supplied to the at least one electrical load, and the control circuit is configured to selectively reduce the power supplied to the at least one electrical load by controlling the TRIAC device to vary a waveform of the AC power signal. Also, in some embodiments, the control circuit is configured to control the TRIAC device to vary the waveform of the AC power signal using a phase control algorithm. Further, in some embodiments, the control circuit is configured to control the TRIAC device to vary the waveform of the AC power signal using the phase control algorithm by controlling an activation delay for the TRIAC device after detection of a zero crossing of the AC power signal.

In some embodiments, the control circuit is configured to control the TRIAC device to vary the waveform of the AC power signal using a cycle skipping algorithm. In addition, in some embodiments, the control circuit is configured to control the TRIAC device to vary the waveform of the AC power signal using the cycle skipping algorithm by selectively deactivating the TRIAC device for one or more half cycles of the AC power signal. In some embodiments, the control circuit is configured to deactivate the TRIAC device for one or more half cycles of the AC power signal by generating a firing pattern for the TRIAC device. In addition, in some embodiments, the control circuit is configured to generate a firing pattern for the TRIAC device by generating an array including a plurality of elements, each element corresponding to a half cycle within a sampling period and indicating whether the TRIAC device is activated during the corresponding half cycle.

Moreover, in some embodiments, the control circuit is configured to control the TRIAC device to vary the waveform of the AC power signal by setting a counter that triggers an interrupt upon reaching an overflow condition to change a state of the TRIAC device. In some embodiments, the control circuit is further configured to control the TRIAC device using a zero cross interrupt service routine that is triggered upon detecting a zero crossing of the AC power signal.

Moreover, in some embodiments, the appliance is a heater and the at least one electrical load includes a resistive heating element. In some embodiments, the appliance is a vacuum and the at least one electrical load includes a universal motor. In addition, in some embodiments, the at least one electrical load is a variable electrical load and the appliance includes at least one non-variable electrical load, and the control circuit is configured to supply full power received over the one or more line power inputs to the at least one non-variable electrical load while selectively reducing the power supplied to the at least one variable electrical load.

In some embodiments, the input power receptacle further includes a control pilot (CP) input, and the demand response signal is received on the CP input. Moreover, in some embodiments, the demand response signal has a duty cycle that varies with the allowed power, and the control circuit is configured to determine the allowed power by determining the duty cycle of the demand response signal.

Also, in some embodiments, the EVSE device operates in at least disconnected, connected but not charging, and charging states, and the control circuit is configured to, upon establishment of the physical connection between the plug and the input power receptacle, automatically cause the EVSE device to transition from the disconnected state to the connected but not charging state, and to, in response to user actuation of a user-actuatable control disposed on the at least one housing when the physical connection between the plug and the input power receptacle is established and the EVSE device is in the connected but not charging state, cause the EVSE device to transition from the connected but not charging state to the charging state and thereby supply power to the one or more line power inputs of the input power receptacle through the plug.

In some embodiments, the input power receptacle includes a control input configured to interface with a corresponding control output of the plug, the control circuit causes the EVSE device to transition from the disconnected state to the connected but not charging state by reducing a voltage at the control output of the plug below a first threshold, and the control circuit causes the EVSE device to transition from the connected but not charging state to the charging state by reducing the voltage at the control output of the plug below a second threshold that is lower than the first threshold. In addition, in some embodiments, the control circuit includes first and second resistors coupled to the control input of the input power receptacle, the first resistor configured to electrically couple the control output of the plug to ground through the first resistor when the physical connection between the plug and the input power receptacle is established, and the second resistor configured to electrically couple the control output of the plug to ground through the second resistor when the user-actuatable control is actuated.

Also, in some embodiments, the user-actuatable control is a first user-actuatable control, and the appliance further includes one or more line power outputs configured to power the at least one electrical load, one or more relays, each configured to selectively couple a respective line power input of the one or more line power inputs to a respective line power output of the one or more line power outputs in response to a respective relay control signal, and a second user-actuatable control coupled to the control circuit, where the control circuit is configured to drive the respective relay control signal of each of the one or more relays to selectively couple together the respective line power input and line power output of each of the one or more relays and thereby selectively power the one or more electrical loads. Moreover, in some embodiments, the input power receptacle is a Society of Automotive Engineers (SAE) J1772 compatible receptacle.

Other embodiments may include various methods of using the various structures as described above.

These and other advantages and features, which characterize the invention, are set forth in the claims annexed hereto and forming a further part hereof. However, for a better understanding of the invention, and of the advantages and objectives attained through its use, reference should be made to the Drawings, and to the accompanying descriptive matter, in which there is described example embodiments of the invention. This summary is merely provided to introduce a selection of concepts that are further described below in the detailed description, and is not intended to identify key or essential features of the claimed subject matter, nor is it intended to be used as an aid in limiting the scope of the claimed subject matter.

### BRIEF DESCRIPTION OF THE DRAWINGS

FIG. 1 is a perspective view of an example embodiment of an EVSE powered appliance consistent with some embodiments of the invention.

FIG. 2 is a flowchart illustrating an example operational sequence for monitoring power in the EVSE powered appliance of FIG. 1.

FIGS. 3A-3C illustrate a circuit diagram of a control circuit usable in the EVSE powered appliance of FIG. 1.

FIG. 4 is a flowchart illustrating an example operational sequence for implementing phase control load shedding in the EVSE powered appliance of FIG. 1.

FIG. 5 is a chart illustrating example waveforms generated by the operational sequence of FIG. 4.

FIG. 6 is a flowchart illustrating an example operational sequence for implementing cycle skipping load shedding in the EVSE powered appliance of FIG. 1.

FIG. 7 is a flowchart illustrating an example operational sequence for setting the array referenced in FIG. 6.

FIG. 8 is a chart illustrating example waveforms generated by the operational sequence of FIG. 6.

### DETAILED DESCRIPTION

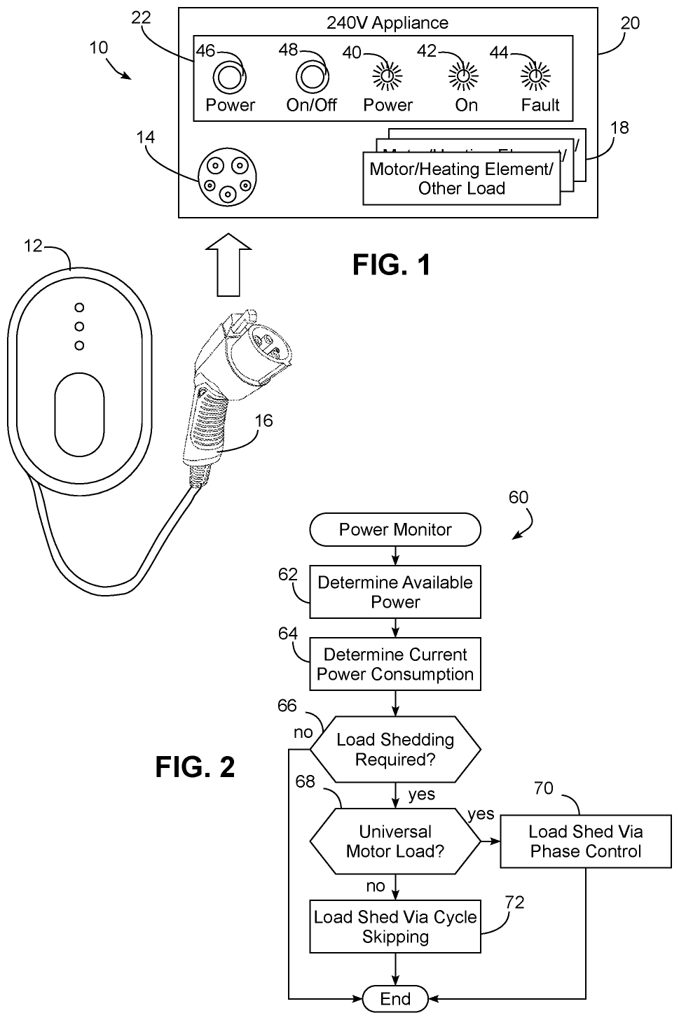

Now turning to the drawings, where like numbers denote like parts throughout the several views, FIG. 1 illustrates an example EVSE powered appliance 10 consistent with some embodiments of the invention. EVSE powered appliance 10 is configured to be powered by an EVSE device 12, and includes an input power receptacle 14 or socket (hereinafter referred to as a receptacle) that is configured to receive a plug or other physical device 16 (hereinafter referred to as a plug) of EVSE device 12 and through which power is supplied to EVSE powered appliance 10.

EVSE device 12, in this regard, may be implemented using any type of device that is generally used to supply electrical power to an electric vehicle in order charge the batteries of the electric vehicle, and may include various devices also referred to as chargers, charging stations or the like. Plug 16 is generally configured to be received by a receptacle disposed on an electric vehicle to establish a physical connection between the plug and receptacle and allow for the flow of electrical energy therebetween.

In the illustrated embodiments, EVSE device 12 is a Level 2 EVSE device that operates using 208-240 VAC, and both receptacle 14 and plug 16 are compatible with the Society of Automotive Engineers (SAE) J1772 standard. However, it will be appreciated by those of ordinary skill having the benefit of the instant disclosure that an EVSE device used in other embodiments may be compliant with different standards, and may have different power outputs or levels, so the invention is not limited to the particular EVSE device for which the illustrated embodiments are specifically configured. Furthermore, it will be appreciated that receptacle 14, and the control circuitry utilized in EVSE powered appliance 10, may vary based upon the specific type of EVSE device with which the EVSE powered appliance 10 is configured to operate.

EVSE powered appliance 10, for example, may be a 240V heater (which, in some instances, could be operated derated at 208V), e.g., a garage heater. EVSE powered appliance 10 may also be a 240V vacuum, e.g., a whole house or shop vacuum system. Examples of other suitable appliances include, but are not limited to, various other types of power tools (e.g., shop tools, arc welders, table saws, woodworking equipment, etc.), appliances, air conditioners, HVAC systems, etc.

Thus, for example, it will be appreciated that user interface 22 and/or housing 20 may be implemented in innumerable different ways that are specific to the particular type of appliance being implemented. The user interface, in particular, may be implemented in some embodiments within the user interface of the overall appliance. In some instances, for example, the EVSE powered appliance 10 may have almost the exact same appearance and function, with the exception of including an input power receptacle that is suitable for receiving the plug of an EVSE device. As but one example, a garage heater implementation of EVSE powered appliance 10 may appear and function exactly like a conventional garage heater with the exception of including an SAE J1772 compatible input power receptacle, and in some instances, a user-actuatable control used to trigger a state transition in the EVSE device, as will be discussed in greater detail below.

For the purpose of interacting with EVSE device 12, user interface 22 of EVSE powered appliance 10 may include one or more lights or indicators, e.g., a power indicator 40, an on indicator 42 and an error indicator 44, as well as one or more user-actuatable controls, e.g., a power user-actuatable control 46 and an on/off user-actuatable control 48. In the illustrated embodiment, user-actuatable controls 46, 48 are implemented as physical, momentary buttons or switches, although it will be appreciated that a wide variety of alternate controls may be used, including other types of buttons, switches, touch sensitive surfaces, knobs, levers, rockers, keys, etc. Likewise, information may be conveyed to a user in other manners than indicators 40-44, e.g., using different lights, or using speakers, haptic actuators, display screens, etc. In some embodiments, for example, an alphanumeric display may be used, or alternatively, a touch screen may be used, to handle one or both of user input and output.

In some embodiments, powering of EVSE powered appliance 10 through EVSE device 12 is implemented in a manner that is compatible with the manner in which an electric vehicle interfaces with an EVSE device. Specifically, many EVSE devices are configured to utilize a handshake procedure with an electric vehicle once a physical connection is established between the EVSE plug and the receptacle on the electric vehicle. The SAE J1772 standard, for example, utilizes two line power connections referred to as L1 and L2, two control connections referred to as control pilot (CP) and proximity pilot (PP), and a ground connection referred to as protective earth (PE). For the purposes of this disclosure, a connection may refer to the establishment of an electrical interface between corresponding connectors, pins, wires, inputs, outputs, etc. of a plug and receptacle, such that power and/or information may be communicated over the connection. In addition, at least for the L1 and L2 connections, the plug may be considered to include L1 and L2 line power outputs, while the input power receptacle may be considered to include L1 and L2 line power inputs. In addition, due to the bidirectional nature of the CP and PP signals, each of the plug and receptacle may be considered to include CP and PP inputs and/or outputs, depending on the context.

The CP connection may be used to switch the EVSE device between at least three different states, referred to herein as disconnected, connected but not charging, and charging states, which under the SAE J1772 standard, are labeled A, B and C respectively. In the disconnected state, the EVSE device does not detect the presence of an electric vehicle, i.e., no physical connection has been established between the plug of the EVSE device and a receptacle of an electric vehicle. In this state the line power connections L1 and L2 are not active, and no line power is supplied through the plug of the EVSE device. Upon detection of a physical connection, a transition occurs to the connected but not charging state, which activates a wave generator in the EVSE device to output a 1 kHz square wave signal, but maintains the L1 and L2 line power connections in the inactive state. When the electric vehicle is ready to charge, the electric vehicle may notify the EVSE device over the CP connection, causing the EVSE device to transition to a charging state, and activate the L1 and L2 line power connections. In addition, once charging has been initiated, the EVSE device is able to communicate the maximum allowed current that the electric vehicle may draw while charging by varying the duty cycle of the square wave signal. It will be appreciated, for example, that some EVSE devices support demand response (DR), which enables a utility company, as an example, to restrict power draw of the EVSE device at certain times of the day, or even shut off the EVSE device entirely for some period of time, either to reduce power consumption during periods of high demand, or to reduce energy costs by deferring charging to the middle of the night, for example.

The manner in which the state transitions occur in the SAE J1772 standard is through control of the voltage of the CP signal. When in the disconnected state, for example, the CP signal has a voltage of about 12 VDC. When the plug is connected to the receptacle of a compatible electric vehicle the resistance of a voltage divider circuit coupled to the CP connection is varied, e.g., by connecting the CP connection to ground through one or more resistors disposed in the electric vehicle to drop the voltage of the CP signal to about 9 VDC, such that the EVSE device can detect the establishment of the physical connection to the electric vehicle by monitoring the voltage of the CP signal. Then, when the electric vehicle is ready to charge, the electric vehicle may connect the CP connection to ground through one or more additional resistors to drop the voltage of the CP signal further (e.g., to about 6 VDC), such that that the EVSE device can initiate the charging operation upon detecting the drop in voltage in the CP signal.

Other EVSE devices and standards may support other handshaking protocols, as well as other control signals and manners of initiating state transfers between the disconnected, connected but not charging and charging states. Therefore, the invention is not limited to the SAE J1772-specific communications discussed herein.

While it is technically possible to emulate an electric vehicle for the purposes of activating the L1 and L2 line power connections of an EVSE device, an EVSE powered appliance as discussed herein presents a unique challenge due to the fact that, unlike an electric vehicle or other device that includes a battery or some independent source of power capable of driving a controller to oversee the emulation and cause activation of the L1 and L2 line power connections, in some embodiments an EVSE powered appliance may have no independent source of power, creating the situation where the circuit logic that would logically be used to emulate an electric vehicle and cause the EVSE device to activate the L1 and L2 line power connections is powered by those very same L1 and L2 line power connections.

Thus, in some embodiments consistent with the invention, a user-actuatable control, e.g., the aforementioned power user-actuatable control 46 of EVSE powered appliance 10 may be used to cause an EVSE device to transition from the connected but not charging state to the charging state and thereby supply power to the L1 and L2 line power connections. A user-actuatable control may, in some embodiments, be considered to refer to a type of a control that is actuated manually by a user, rather than automatically or through the use of control logic. As noted above, a wide variety of user-actuatable controls may be used in various embodiments, so the invention is not limited to the particular user-actuatable controls discussed hereinafter, specifically momentary push buttons.

Specifically, in an SAE J1772-compatible system, and as will be discussed in greater detail below, a control circuit of an EVSE powered appliance consistent with some embodiments of the invention may cause the EVSE device to transition from the disconnected state to the connected but not charging state by reducing a voltage at the CP connection below a first threshold, and cause the EVSE device to transition from the connected but not charging state to the charging state by reducing the voltage at the control output of the plug below a second threshold that is lower than the first threshold, in part using the aforementioned user-actuatable control. Further, the manner in which the voltage reductions may occur in some embodiments using first and second resistors coupled to the CP connection, with the first resistor configured to electrically couple the CP connection to ground through the first resistor when the physical connection between the plug and the input power receptacle is established, and with the second resistor configured to electrically couple the CP connection to ground through the second resistor when the user-actuatable control is actuated. Of note, therefore, the transition from the disconnected state to the connected but not charging state is automatically performed in response to establishment of the physical connection between the plug and the input power receptacle, while the transition from the connected but not charging state to the charging state is user-initiated, i.e., in response to user input directed to a user-actuatable control.

Among other benefits, the use of a user-actuatable control is the herein-disclosed manner enables an EVSE powered appliance such as EVSE powered appliance 10 to omit any battery or alternative power source capable of driving programmable logic to interact with an EVSE device to cause the EVSE device to initiate charging. Doing so may have particular benefit since a single input power receptacle may be used to power the EVSE powered appliance despite the fact that no usable power is effectively supplied to the EVSE powered appliance by the EVSE device prior to (a) establishing the physical connection with the plug and the input power receptacle, and (b) actuating the user-actuatable control to cause the EVSE device to transition to the charging state. It will be appreciated, in particular, that many of the types of appliances discussed herein for EVSE powered appliance 10 do not ordinarily include batteries, and are often used and/or stored in harsh conditions, so the introduction of a separate battery could add to the cost of such devices and/or introduce additional sources of failure down the road.

Embodiments consistent with the invention also support load shedding to allow an EVSE powered appliance to continue operating at a derated power level as allowed by an EVSE device. In particular, as electric vehicles continue to expand market share, the number of homes with garage or carport installed Level 2 (208/240 VAC) EVSE devices will also grow. Further, many of these EVSE devices will be subsidized by local utilities under the condition that the EVSE devices be “demand response” (DR) capable. At times of peak load, utilities may send EVSE devices a command to reduce the rate of charging, or even to stop charging completely. As noted above, SAE J1772-compatible systems may implement demand response through control over the CP signal, typically through control of the duty cycle of the CP signal.

Embodiments consistent with the invention may support load shedding using a control circuit that, in response to a demand response signal received from an EVSE device, selectively reduces the power supplied to one or more electrical loads while the electrical load(s) are active to reduce power consumption by the electrical load(s) to meet an allowed power (e.g., in terms of an allowed current in some embodiments) indicated by the demand response signal. In the illustrated embodiments, for example, phase control and/or cycle skipping may be implemented to controllably decrease the power consumption of one or more variable loads in an EVSE powered appliance using a bidirectional triode thyristor (also referred to herein as a TRIAC or TRIAC device) to vary a waveform of the AC power signal, and generally without the need for power conversion.

With a phase control approach or algorithm, the TRIAC device is controllably shut off for at least a portion of each cycle of the AC power signal, with the duration of the shut off period increased to progressively reduce the power available to the EVSE powered appliance. In some embodiments, for example, a controllable activation delay may be used to effectively delay activation of the TRIAC device after detection of a zero crossing of the AC power signal, such that for each cycle, or in some instances, each half cycle, no current is supplied to the electrical load(s) in the period between the zero crossing and the activation of the TRIAC device. With a cycle skipping approach or algorithm, the TRIAC device is selectively deactivated for one or more cycles or half cycles over a time window to progressively reduce the power available to the EVSE powered appliance, such that, for some cycles or half cycles, no current is supplied to the electrical load(s).

While other approaches, such as an AC-DC-AC inverter, may also be used in some embodiments, a TRIAC-based approach as described herein is generally more compact and less expensive than an inverter-based approach. As will become more apparent below, however, phase control and cycle skipping may be useful for variable loads such as heating elements (e.g., resistive heaters) and universal motors (similar to series connected DC brush motors). However, for an EVSE powered appliance with a large induction motor load, an inverter-based approach would generally be more appropriate as induction motors are generally designed to run on 50/60 Hz sinewave power.

Nonetheless, it will be appreciated that in some EVSE powered appliances, some loads may have a negligible impact on overall power consumption, and thus may be used even if not suitable for load shedding using phase control and/or cycle skipping. As such, in some embodiments, an EVSE powered appliance may also include other, non-variable loads that are not regulated (i.e., that still receive full AC voltage) even when other variable loads are being regulated. For example, for a heater, a heater fan driven by an induction motor (which generally represents a small fraction of the overall power consumption of the heater) may be treated as a non-variable load, and powered using full AC voltage even when the heating element is being throttled.

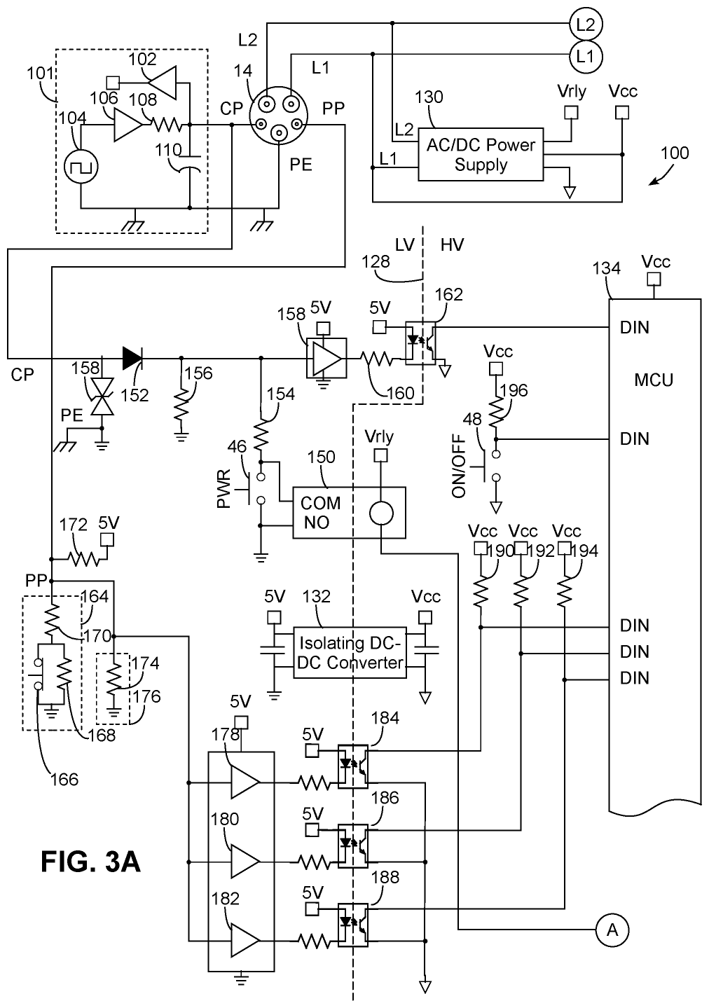

FIG. 2, for example, illustrates an example operational sequence 60 that may be implemented by EVSE powered appliance 10 to monitor and regulate power consumption of the EVSE powered appliance. Sequence 60 may be executed, for example, on a periodic basis to monitor and regulate the power consumption of the EVSE powered appliance while it is active. In block 62, available power may be determined, e.g., in response to a demand response signal such as a CP signal. In block 64, current power consumption may be determined, e.g., by sensing current draw by the EVSE powered appliance 10. Based upon a comparison of the available power and current power consumption, block 66 may determine if load shedding is required. If not, sequence 60 is complete. Otherwise, control passes to block 68 to determine whether the load used by the EVSE powered appliance is a universal motor load. If so, control passes to block 70 to perform load shedding via phase control. Otherwise (e.g., in the case of a resistive heating element), block 78 may pass control to block 72 to perform load shedding via cycle skipping.

It will be appreciated that for different types of variable loads, different approaches may be more desirable. Universal motors, for example, may be regulated more efficiently using phase control, while resistive elements may be regulated by either approach, but with cycle skipping generally providing lower harmonic emissions. It will also be appreciated that, for example, if a particular EVSE powered appliance only includes a variable load that is suitable for one particular type of load shedding approach, support for both types may be omitted. Thus, for example, block 68 and one of blocks 70 and 72 may be omitted from sequence 60 in some embodiments.

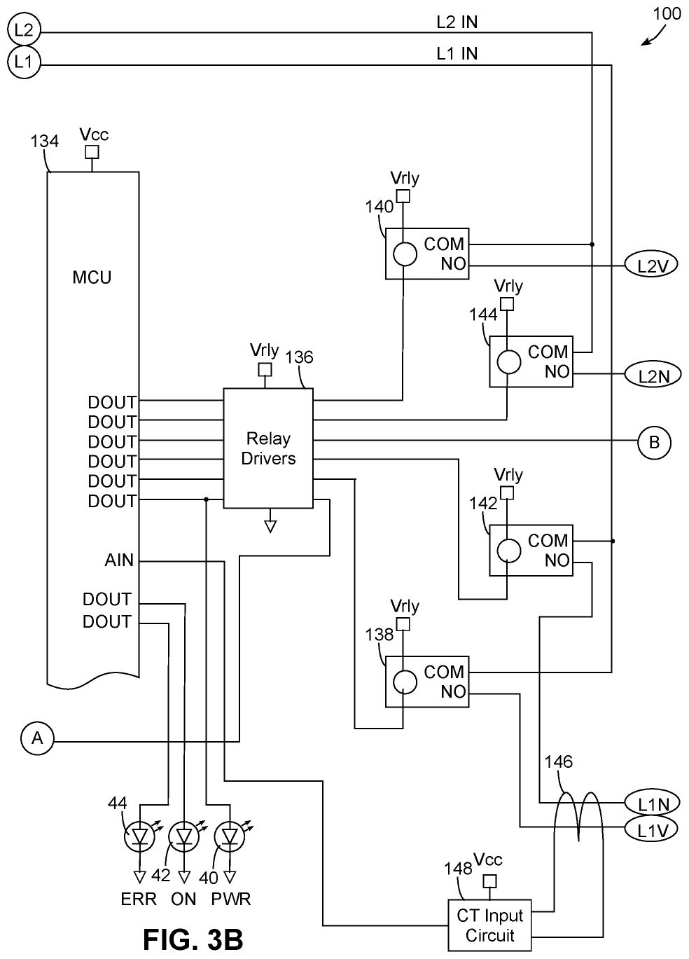

Now turning to FIGS. 3A-3C, this figure illustrates a control circuit 100 that may be used in some embodiments for EVSE powered appliance 10 of FIG. 1, along with several additional circuits incorporated into an EVSE device and delimited by dashed lines with which control circuit 100 interacts.

As an example, circuit 101 is used to generate the CP signal seen at the CP input of input power receptacle 14. A buffer 102 is used to sense the voltage of the CP signal for the purposes of state transitions, and a pilot oscillator 104 is used to generate a +/−12 VDC 1 kHz square wave signal, with a driver 106 configured to drive this signal through a resistor 108 coupled to the CP input. A small capacitor 110 is also coupled between the input to buffer 102 and resistor 108 and ground to reduce dV/dt and minimize problems such as ringing that high dV/dt may cause at the receiving end of the charging cable.

In this embodiment, load shedding is implemented using a TRIAC 112 (FIG. 3C) coupled between a pair of variable power lines L1V, L2V, which may be controlled to selectively reduce the current supplied to, and thus the power consumed by, one or more variable loads coupled to the variable power lines. A variable load, within the context of the present disclosure, may be considered to be a load capable of operating at a reduced output level through control of TRIAC 112 by control circuit 100 using phase control and/or cycle skipping. Two alternate appliance implementations are illustrated, including an implementation as an electric heater 114 including one or more heating elements 116, and an implementation as a vacuum cleaner 118 including a universal motor 120. In either implementation, however, it will be appreciated that additional, non-variable loads may also be present within an EVSE powered appliance, e.g., an induction motor used by a heater fan 122, or another non-variable load 124 in vacuum cleaner 118. For the purpose of controlling these non-variable loads 122, 124, an additional pair of non-variable power lines L1N, L2N may be provided, although in some embodiments, no non-variable loads may be present, so the circuitry associated with driving non-variable power lines L1N, L2N may be omitted. A heat sink 126 may also be provided to cool TRIAC 112.

Also, in control circuit 100, isolation is provided between portions of the control circuit that are interfaced with EVSE device 12, which are referenced to earth ground, and portions of the control circuit that are interfaced with TRIAC 112. The isolation is represented by dashed line 128 (FIG. 3A), with the circuitry to the left of line 128 designated as the low voltage (LV) portion, and the circuitry to the right of line 128 designated as the high voltage (HV) portion. An AC/DC power supply 130 is coupled across power lines L1 and L2 to generate Vcc and Vrly power signals, the former of which is used to drive the circuit logic in the high voltage portion and the latter of which is used to drive various relays discussed hereinafter. The output Vcc is connected to L1 so that TRIAC 112 can be operated in quadrants 2 and 3. An isolating DC-DC converter 132 (FIG. 3A) provides a 5 VDC power signal to the LV portion.

As illustrated in FIG. 3B, microcontroller 134 drives a relay driver 136, which in turns drives a set of power relays 138, 140, 142, 144 that control the state of the L1V, L2V, LIN, and L2N power lines, respectively. For the purpose of monitoring the load current, a current transformer 146 senses current in power lines L1V and LIN and is coupled to a CT input circuit 148 that couples to an analog input of microcontroller 134 and conditions the signal appropriately, e.g., by amplifying/attenuating and/or adding DC bias if needed. Relay driver 136 is also coupled to a charging relay 150 (FIG. 3A) that is coupled in parallel with power user-actuatable control 46, and is driven by a digital output of microcontroller 134. The CP signal is coupled to this parallel arrangement through a diode 152 and a resistor 154, and another resistor 156 is coupled between the junction of diode 152 and resistor 154 and ground. A TVS diode 158 is also coupled between the CP connection and ground.

Of note, resistor 156 is used to initiate the state transition from the disconnected state to the connected but not charging state, as when a physical connection is established, resistor 156 is introduced into the circuit to couple the CP connection to ground and lower the voltage of the CP signal accordingly, thereby enabling the sensing logic in the EVSE device to detect the physical connection.

Likewise, resistor 154, which is connected to ground in series with the parallel arrangement of user-actuated control 46 and charging relay 150, is used to initiate the state transition from the connected but not charging state to the charging state, as when either user-actuated control 46 (which may be a normally-open momentary push button) or charging relay 150 is closed, resistor 154 is introduced into the circuit to couple the CP connection to ground and further lower the voltage of the CP signal accordingly, thereby enabling the sensing logic in the EVSE device to detect the instruction to initiate charging. Of note, because user-actuated control 46 is momentary, it is desirable for microcontroller 134 to close charging relay 150 once it has powered up such that the EVSE device will not revert from the charging state once the user-actuated control 46 is released. In addition, charging relay 150 provides microcontroller 134 with a programmatic option to instruct the EVSE device to discontinue charging if desired.

The junction of diode 152 and resistors 154 and 156 is also coupled to a comparator 158 that provides a representation of the CP signal to a digital input of microcontroller 134 through a resistor 160 and opto-isolator 162.

For the PP connection, and as illustrated by circuit 164, the plug of the EVSE device includes a normally closed switch 166 that opens whenever a release actuator of the plug is pressed, and is an indicator of when a user is about to plug in or unplug a plug to or from a receptacle, and enables the EVSE device (and an electric vehicle) to perform a controlled shut off prior to the L1 and L2 connections being physically disconnected. Switch 166 is coupled to ground in parallel with resistor 168, and the parallel arrangement is coupled to the PP connection through a resistor 170.

The PP connection is also coupled to a set of three comparators 178, 180, 182, which couple to digital inputs of microcontroller 134 through opto-isolators 184, 186, 188 and to the Vcc power supply through resistors 190, 192, 194. Comparators 178, 180, 182 respectively detect (1) plug disconnected, (2) plug connected, and (3) plug connected with switch 166 closed states. An on/off user-actuatable control 48, which may be a normally-open momentary push button, is coupled to the Vcc power supply by a resistor 196, and to a digital input of microcontroller 134. Moreover, as illustrated in FIG. 3B, the power, on and error indicators 40, 42 and 44 may be driven by microcontroller 134.

With reference to FIG. 3C, a zero-cross detect circuit 198 signals zero crossings across the L1V/L2V lines to a digital input of microcontroller 134. A bypass relay 200, driven by microcontroller 134 via relay driver 136, may be used to bypass TRIAC 112 and supply full power to the variable loads. In addition, TRIAC 112 is controlled by microcontroller 134 through a gate drive circuit 202 including a drive transistor 204 and resistors 206-212. The base of transistor 204 is coupled to a digital output of microcontroller 134 through resistor 206 and to ground through resistor 208, and the emitter is coupled to ground. The gate of TRIAC 112 is coupled to the collector of transistor 204 through resistor 210, and to ground through resistor 212.

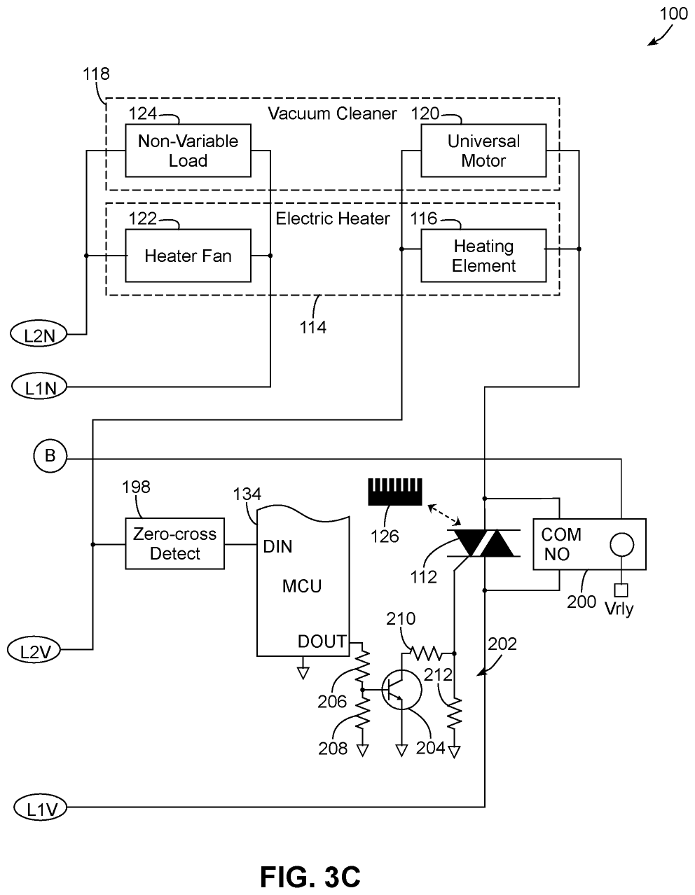

Now turning to FIG. 4, an example operational sequence for implementing phase control-based load shedding is illustrated at 220. In this sequence, the duty cycle (DutyIn) of the CP signal is received at a digital input of the microcontroller (block 222) and the allowed current (I_Allowed) is determined in block 224 as the product of DutyIn and 60 A, e.g., such that a 50% duty cycle corresponds to a 30 A allowed current. Block 226 determines a different between the allowed current and an actual current (I_RMS) determined in block 228. The actual RMS current is determined by sensing with a current transformer 230 the current being drawn by the various loads 232 in the EVSE powered appliance, conditioning the signal output by current transformer 230 with a current transformer input circuit 234, converting the analog output of circuit 234 to a digital value using an analog-to-digital converter (ADC) 236 in the microcontroller, and determining therefrom the RMS current in block 236.

The difference output by block 226, I_Delta, is fed to a proportional integral control circuit including a proportional gain block 237, an integral gain block 238, a summation block 240, a clamp 242, a previous value block 244, a summer 246, and a clamp 248 to generate a count value (TimerCounts) to be set in an 8-bit timer (TMR) that schedules an overflow interrupt in which TRIAC firing will occur, enabling the microcontroller to control a gate drive circuit 250 (similar to gate drive circuit 202 of FIG. 3C) to drive a TRIAC 252 coupled in series with loads 232. Proportional and integral gain blocks 237, 238 each receive I_Delta, and integral gain block 238 outputs the amplified signal to summer 240. The output of summer 240 is fed to clamp 242, and is then fed back to the other input of summer 240 through previous value block 244. The output of proportional gain block 237 and the output of clamp 242 are fed as inputs to summer 246, which then outputs the sum to clamp 248, resulting in the generation of the TimerCounts value.

Clamps 242, 248 bind the TimerCounts value between maximum (Max Counts) and minimum (Min Counts) values. In the illustrated embodiment, each count of the timer corresponds to 64 us of delay, and MaxCounts may be set to 255, which causes an almost immediate overflow, while MinCounts may be set to 140, which causes an overflow to occur in 116 (256-140) cycles, or 7.42 ms (64 us*116), which is approximately 160 degrees after zero-cross in a 60 Hz system.

A pair of interrupt service routines (ISRs) 254, 256 control the timing of TRIAC 252 firing. ISR 254 is a zero cross ISR, which is called in response to detection of a zero crossing in the AC power signal supplied to the variable loads across L1V, L2V (e.g., as sensed by zero-cross detect circuit 198 of FIG. 3C). When ISR 254 is called, block 258 sets the count for timer TMR (TCNT) to the previously-determined TimerCounts value, and block 260 enables the TMR overflow interrupt, thereby initiating the counter to increment about every 64 us until an overflow condition occurs. ISR 256 handles such an overflow, and begins in block 262 by determining whether TRIAC 252 is currently on. If not, control passes to block 264 to turn on the TRIAC, and then to block 266 to set the count for timer TMR (TCNT) to 244, which effectively schedules the TRIAC to be turned off in (256−244)*64 us=768 us, which is approximately 16.6 degrees after being turned on. Thus, upon a second triggering of the TMR overflow interrupt once the TRIAC is on, ISR 256 again executes, with block 262 determining that the TRIAC is on and passing control to block 268 to turn off the TRIAC, and then to block 270 to disable the TMR overflow interrupt.

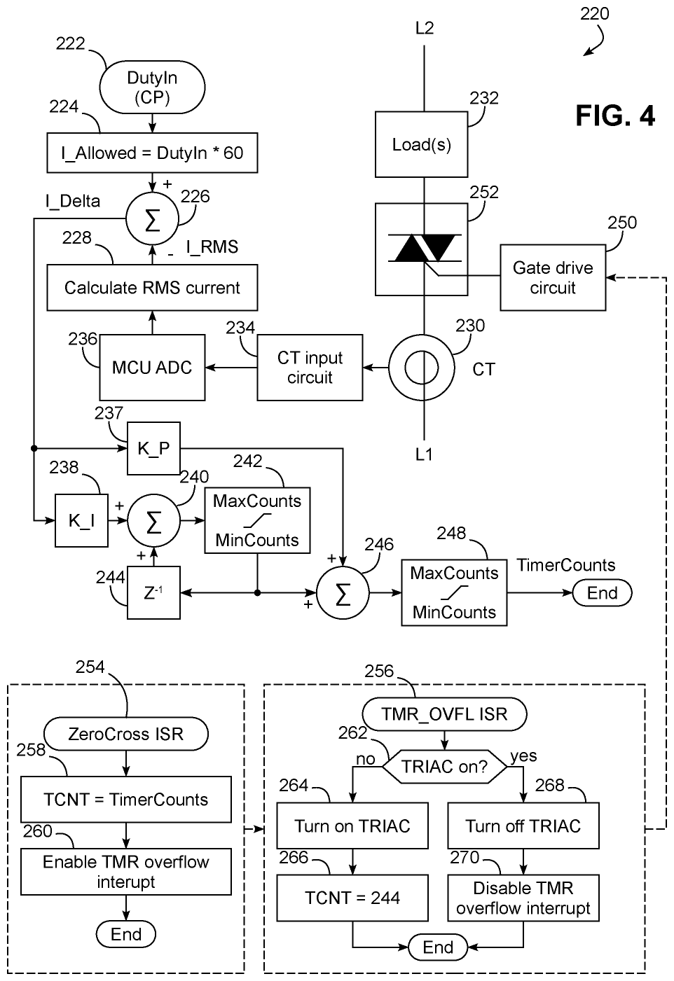

Thus, in operational sequence 220, a variable phase shift may be applied to delay activation of the TRIAC at each zero crossing and thereby controllably reduce the amount of power supplied to the variable loads responsive to the amount of available power as determined by the CP signal duty cycle. FIG. 5, for example, illustrates at 280 a non-throttled AC power signal, along with a moderately throttled AC power signal 282 capable of being generated in the manner discussed above in connection with operational sequence 220.

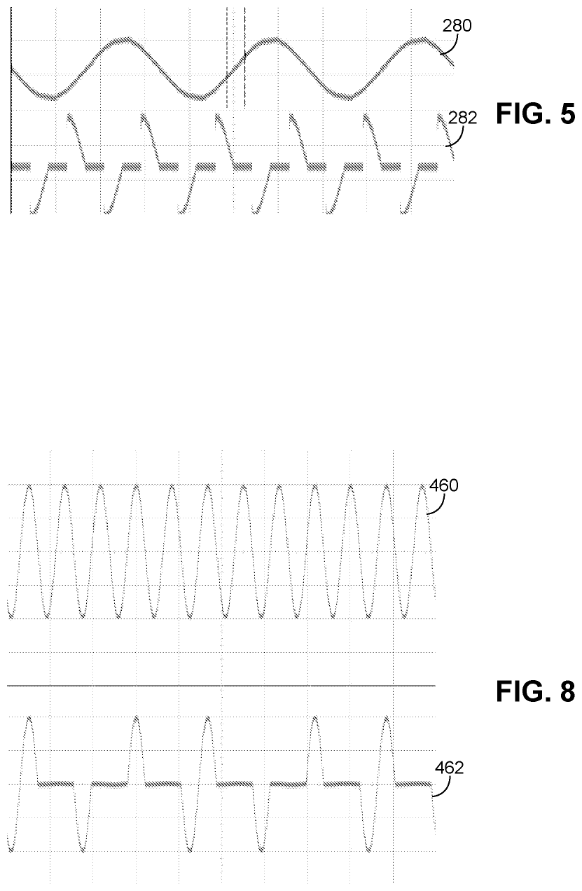

Now turning to FIG. 6, an example operational sequence for implementing cycle skipping-based load shedding is illustrated at 300. In this sequence, the duty cycle (DutyIn) of the CP signal is received at a digital input of the microcontroller (block 302) and the allowed current (I_Allowed) is determined in block 304 as the product of DutyIn and 60A, e.g., such that a 50% duty cycle corresponds to a 30A allowed current. Block 306 determines a different between the allowed current and an actual current (I_RMS) determined in block 308. The actual RMS current is determined by sensing with a current transformer 310 the current being drawn by the various loads 312 in the EVSE powered appliance, conditioning the signal output by current transformer 310 with a current transformer input circuit 314, converting the analog output of circuit 314 to a digital value using an analog-to-digital converter (ADC) 316 in the microcontroller, and determining therefrom the RMS current in block 306.

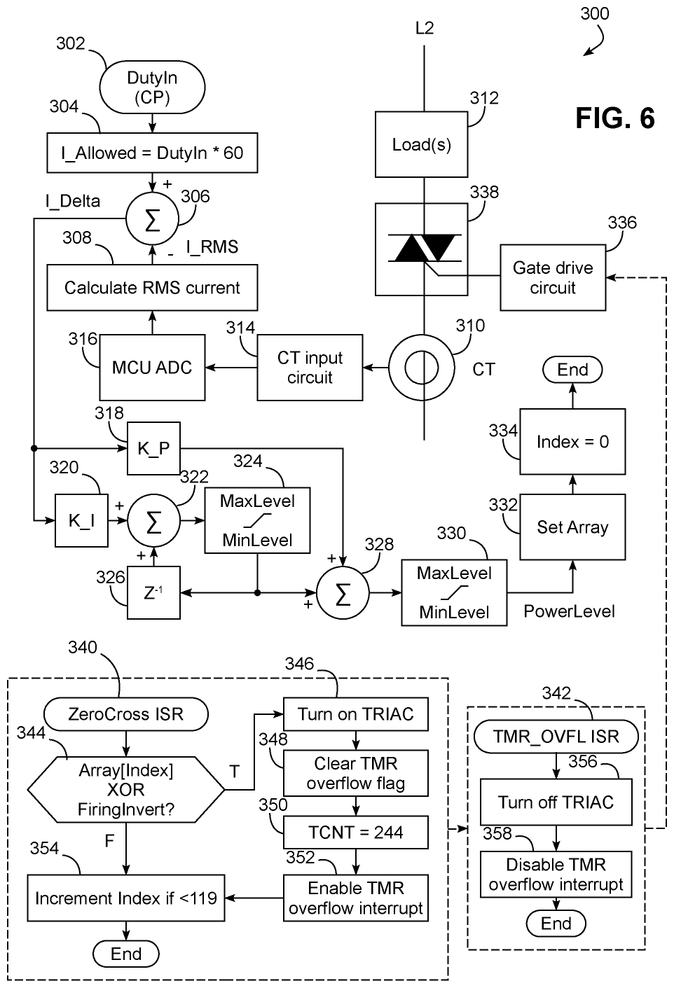

The difference output by block 306, I_Delta, is fed to a proportional integral control circuit including a proportional gain block 318, an integral gain block 320, a summation block 322, a clamp 324, a previous value block 326, a summer 328, and a clamp 330 to generate a power level value (PowerLevel) representing the amount of power to be supplied based upon the allowed current. The PowerLevel value is used to configure a 120 element array in block 332 (discussed in greater detail below in connection with FIG. 7) that defines a firing pattern for the TRIAC device, and an index to the array is set to 0 in block 334. The array is used to control a gate drive circuit 336 (similar to gate drive circuit 202 of FIG. 3C) to selectively drive a TRIAC 338 coupled in series with loads 312.

The array includes 120 1-bit elements generally corresponding to the 120 half cycles in one second of the 60 Hz AC power signal, such that the T/F state of each element in the array may be used to control the active/inactive state of TRIAC 338 during the corresponding half cycle for that array element.

Proportional and integral gain blocks 318, 320 each receive I_Delta, and integral gain block 320 outputs the amplified signal to summer 322. The output of summer 322 is fed to clamp 324, and is then fed back to the other input of summer 322 through previous value block 326. The output of proportional gain block 318 and the output of clamp 324 are fed as inputs to summer 328, which then outputs the sum to clamp 330, resulting in the generation of the PowerLevel value.

Clamps 324, 330 bind the PowerLevel value between maximum (MaxLevel) and minimum (MinLevel) values. In the illustrated embodiment, a one second sampling interval is used, and as such, the PowerLevel may be bound between MinLevel=0 and MaxLevel=60 for a 60 Hz AC power signal. In addition, as will be discussed in greater detail below, a separate FiringInvert flag, which is set when PowerLevel is above a half power threshold, is also used to invert the firing pattern used to control the activation of the TRIAC.

A pair of interrupt service routines (ISRs) 340, 342 control the timing of TRIAC 338 firing, and similar to operational sequence 220, operational sequence 300 uses an 8-bit timer (TMR) to schedule an overflow interrupt, but to do so in order to turn off the TRIAC after it has been activated. ISR 340 is a zero cross ISR, which is called in response to detection of a zero crossing in the AC power signal supplied to the variable loads across L1V, L2V (e.g., as sensed by zero-cross detect circuit 198 of FIG. 3C). When ISR 340 is called, block 334 performs an Exclusive OR of the currently indexed element of the array with the FiringInvert flag, such that the FiringInvert flag essentially inverts the currently indexed element when set. If the XOR result is true, the TRIAC is scheduled to be active during the current half cycle, so control passes to block 346 to turn on the TRIAC. Block 348 then clears the TMR overflow flag, and block 350 sets the count for timer TMR (TCNT) to 244, which effectively schedules the TRIAC to be turned off in (256−244)*64 us=768 us. The TMR overflow interrupt is then enabled in block 352, and Index is incremented (block 354) if Index is less than 119. Returning to block 344, if the result of the Exclusive OR is false, blocks 346-352 are bypassed, and the Index is simply incremented in block 354.

ISR 342 handles the TMR overflow interrupt, and as noted above, is generally triggered about 768 us after TRIAC 338 is turned on after a zero crossing is detected. Thus, when called, ISR 342 turns off the TRIAC in block 356, and disables the TMR overflow interrupt in block 358.

It will be appreciated that the manner of setting the array in block 332 to implement cycle skipping to reduce the power supplied to the variable loads may vary in different embodiments. FIG. 7, for example, illustrates an example operational sequence 400 that may be used to implement block 332 of FIG. 6 in some embodiments. While not required, sequence 400 in FIG. 7 is configured to return the value of the FiringInvert flag.

In this sequence, the array is initially cleared in block 402, and block 404 determines whether the PowerLevel value input to the sequence exceeds a HalfPower threshold corresponding to about 50% of available power, e.g., 30 when PowerLevel is constrained to 0 . . . 60. If not, control passes to block 406 to clear the FiringInvert flag, and block 408 determines whether PowerLevel is zero, corresponding to minimum power. If so, control passes to block 410 to return a value of “false” for the FiringInvert flag, and the sequence is complete, and it should be noted that as a result of the array being cleared in block 402, the TRIAC will effectively be disabled over the entire sampling interval, thereby cutting power to the variable loads.

Otherwise, block 408 passes control to block 412 to set Interval, Remain, Index and LoopCounter variables used to set the array. Interval is the integer divide of FullPower, corresponding to the maximum value for PowerLevel (e.g., 60 when PowerLevel is constrained to 0 . . . 60), by PowerLevel, while Remain is the remainder of the integer divide. Index is an index into the array, and LoopCounter is a variable used as a counter for the loop of sequence 400.

Returning to block 404, if PowerLevel is greater than HalfPower, control passes to block 414 to set PowerLevel to the difference between FullPower and PowerLevel, and then to block 416 to set the FiringInvert flag. Block 418 determines whether PowerLevel is zero, corresponding to maximum power (given the difference taken in block 414). If so, control passes to block 420 to return a value of “true” for the FiringInvert flag, and the sequence is complete, and it should be noted that as a result of the array being cleared in block 402, and the FiringInvert flag being set, the TRIAC will effectively be enabled over the entire sampling interval, thereby providing full power to the variable loads. Otherwise, control passes to block 412 to set Interval, Remain, Index and LoopCounter in the manner discussed above.

Block 412 next passes control to block 422 to initiate a loop to populate the array based upon the Interval and Remain values determined above. Block 422 performs a modulus by 2 of the sum of LoopCounter and Index to effectively determine if the sum is even or odd. If even, control passes to block 424 to set the array element at the current index to true. If odd, control instead passes to block 426 to set the array element at the current index+1 to true. After either of blocks 424, 426, block 428 determines whether Remain=0, and if not, passes control to block 430 to determine if an integer divide of LoopCounter by PowerLevel is less than Remain, and if so, increments Index by Interval+1. Returning to block 430, if a negative result is determined, control instead passes to block 434 to increment Index by the value of Interval. Furthermore, returning to block 428, if Remain is zero, control passes to block 436 to increment Index by the value of Interval.

Upon completion of any of blocks 432, 434, and 436, control passes to block 438 to determine if LoopCounter is less than 2*PowerLevel, and if so, to increment LoopCounter and return control to block 422. If not, however, control passes to block 440 to determine the state of the FiringInvert flag. If true, control passes to block 442 to return a true value as a result of the sequence, and if false, control passes to block 444 to return a false value as a result of the sequence.

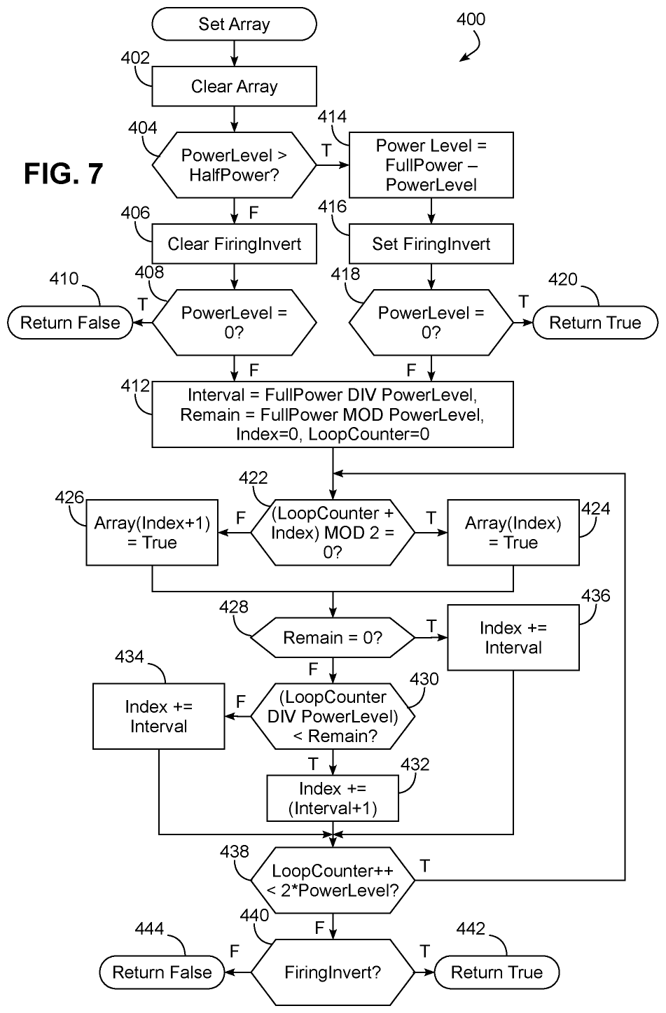

Thus, in operational sequences 300 and 400, an activation pattern for the TRIAC during each of 120 half cycles over a one second sampling interval is generated that progressively decreases the number of active half cycles (and increases the number of skipped half cycles) responsive to decreases in the amount of available power as determined by the CP signal duty cycle. FIG. 8, for example, illustrates at 460 a non-throttled AC power signal, along with a moderately throttled AC power signal 462 capable of being generated in the manner discussed above in connection with operational sequences 300 and 400.

It will be appreciated that implementation of the various operations disclosed in FIGS. 4 and 6-7, as well as implementation of the control circuit of FIGS. 3A-3C, would be well within the abilities of those of ordinary skill having the benefit of the instant disclosure. Moreover, it will be appreciated that, while certain features may be discussed herein in connection with certain embodiments and/or in connection with certain figures, unless expressly stated to the contrary, such features generally may be incorporated into any of the embodiments discussed and illustrated herein. For example, in some embodiments, both phase control and cycle skipping may be used, e.g., where an appliance includes both a heating element and a universal motor, and indeed, control circuit 100 described above may implement both types of load shedding using the same hardware components. Moreover, features that are disclosed as being combined in some embodiments may generally be implemented separately in other embodiments, and features that are disclosed as being implemented separately in some embodiments may be combined in other embodiments, so the fact that a particular feature is discussed in the context of one embodiment but not another should not be construed as an admission that those two embodiments are mutually exclusive of one another. Various additional modifications may be made to the illustrated embodiments consistent with the invention. Therefore, the invention lies in the claims hereinafter appended.

What is claimed is:

1. An appliance configured to receive power from an Electric Vehicle Supply Equipment (EVSE) device, the appliance comprising:
at least one housing;
an input power receptacle disposed on the at least one housing and configured to receive the plug of the EVSE device to establish a physical connection therebetween, the input power receptacle including one or more line power inputs configured to receive power from the plug of the EVSE device;
at least one electrical load disposed in the at least one housing; and
a control circuit coupled to the input power receptacle and the at least one electrical load to supply power received over the one or more line power inputs to the at least one electrical load, the control circuit further configured to, in response to a demand response signal received from the EVSE device through the input power receptacle, selectively reduce the power supplied to the at least one electrical load while the at least one electrical load is active to reduce power consumption by the at least one electrical load to meet an allowed power indicated by the demand response signal.

2. The appliance of claim 1, wherein the control circuit is configured to supply power to the at least one electrical load using an alternating current (AC) power signal received over the one or more line power inputs, wherein the control circuit includes a TRIAC device configured to control the power supplied to the at least one electrical load, and wherein the control circuit is configured to selectively reduce the power supplied to the at least one electrical load by controlling the TRIAC device to vary a waveform of the AC power signal.

3. The appliance of claim 2, wherein the control circuit is configured to control the TRIAC device to vary the waveform of the AC power signal using a phase control algorithm.

4. The appliance of claim 3, wherein the control circuit is configured to control the TRIAC device to vary the waveform of the AC power signal using the phase control algorithm by controlling an activation delay for the TRIAC device after detection of a zero crossing of the AC power signal.

5. The appliance of claim 2, wherein the control circuit is configured to control the TRIAC device to vary the waveform of the AC power signal using a cycle skipping algorithm.

6. The appliance of claim 5, wherein the control circuit is configured to control the TRIAC device to vary the waveform of the AC power signal using the cycle skipping algorithm by selectively deactivating the TRIAC device for one or more half cycles of the AC power signal.

7. The appliance of claim 6, wherein the control circuit is configured to deactivate the TRIAC device for one or more half cycles of the AC power signal by generating a firing pattern for the TRIAC device.

8. The appliance of claim 7, wherein the control circuit is configured to generate a firing pattern for the TRIAC device by generating an array including a plurality of elements, each element corresponding to a half cycle within a sampling period and indicating whether the TRIAC device is activated during the corresponding half cycle.

9. The appliance of claim 2, wherein the control circuit is configured to control the TRIAC device to vary the waveform of the AC power signal by setting a counter that triggers an interrupt upon reaching an overflow condition to change a state of the TRIAC device.

10. The appliance of claim 9, wherein the control circuit is further configured to control the TRIAC device using a zero cross interrupt service routine that is triggered upon detecting a zero crossing of the AC power signal.

11. The appliance of claim 1, wherein the appliance is a heater and the at least one electrical load includes a resistive heating element.

12. The appliance of claim 1, wherein the appliance is a vacuum and the at least one electrical load includes a universal motor.

13. The appliance of claim 1, wherein the at least one electrical load is a variable electrical load and the appliance includes at least one non-variable electrical load, and wherein the control circuit is configured to supply full power received over the one or more line power inputs to the at least one non-variable electrical load while selectively reducing the power supplied to the at least one variable electrical load.

14. The appliance of claim 1, wherein the input power receptacle further includes a control pilot (CP) input, wherein the demand response signal is received on the CP input.

15. The appliance of claim 14, wherein the demand response signal has a duty cycle that varies with the allowed power, and the control circuit is configured to determine the allowed power by determining the duty cycle of the demand response signal.

16. The appliance of claim 1, wherein the EVSE device operates in at least disconnected, connected but not charging, and charging states, wherein the control circuit is configured to, upon establishment of the physical connection between the plug and the input power receptacle, automatically cause the EVSE device to transition from the disconnected state to the connected but not charging state, and to, in response to user actuation of a user-actuatable control disposed on the at least one housing when the physical connection between the plug and the input power receptacle is established and the EVSE device is in the connected but not charging state, cause the EVSE device to transition from the connected but not charging state to the charging state and thereby supply power to the one or more line power inputs of the input power receptacle through the plug.

17. The appliance of claim 16, wherein the input power receptacle includes a control input configured to interface with a corresponding control output of the plug, wherein the control circuit causes the EVSE device to transition from the disconnected state to the connected but not charging state by reducing a voltage at the control output of the plug below a first threshold, and wherein the control circuit causes the EVSE device to transition from the connected but not charging state to the charging state by reducing the voltage at the control output of the plug below a second threshold that is lower than the first threshold.

18. The appliance of claim 17, wherein the control circuit includes first and second resistors coupled to the control input of the input power receptacle, the first resistor configured to electrically couple the control output of the plug to ground through the first resistor when the physical connection between the plug and the input power receptacle is established, and the second resistor configured to electrically couple the control output of the plug to ground through the second resistor when the user-actuatable control is actuated.

19. The appliance of claim 16, wherein the user-actuatable control is a first user-actuatable control, the appliance further comprising:
one or more line power outputs configured to power the at least one electrical load;
one or more relays, each configured to selectively couple a respective line power input of the one or more line power inputs to a respective line power output of the one or more line power outputs in response to a respective relay control signal; and
a second user-actuatable control coupled to the control circuit;
wherein the control circuit is configured to drive the respective relay control signal of each of the one or more relays to selectively couple together the respective line power input and line power output of each of the one or more relays and thereby selectively power the one or more electrical loads.

20. The appliance of claim 1, wherein the input power receptacle is a Society of Automotive Engineers (SAE) J1772 compatible receptacle.
